(19) United States
(12) Patent Application Publication
(10) Pub. No.: US 2023/0389303 A1
(43) Pub. Date: Nov. 30, 2023

(54) MEMORY DEVICES AND METHODS FOR OPERATING THE SAME

(71) Applicant: Taiwan Semiconductor Manufacturing Company, Ltd., Hsinchu (TW)

(72) Inventor: Hsiang-Wei Liu, Tainan City (TW)

(73) Assignee: Taiwan Semiconductor Manufacturing Company, Ltd., Hsinchu (TW)

(21) Appl. No.: 17/752,580

(22) Filed: May 24, 2022

(51) Int. Cl. H01L 27/112; G11C 17/16

(52) U.S. Cl. CPC H01L 27/11206; G11C 17/165

(57) ABSTRACT

A memory device includes a first memory cell including a first transistor and a first anti-fuse structure electrically coupled to each other in series. The first transistor includes a first gate structure extending across an active region, a first source/drain structure disposed in a first portion of the active region, and a second source/drain structure disposed in a second portion of the active region. The first anti-fuse structure includes a first electrode electrically coupled to the first source/drain structure, a second electrode disposed over a first dummy gate structure, and a first insulator laterally interposed between the first electrode and the second electrode.

### BACKGROUND

Integrated circuits (ICs) sometimes include one-time-programmable (OTP) memories to provide non-volatile memory (NVM) in which data are not lost when the IC is powered off. One type of the OTP devices includes anti-fuse memory devices. The anti-fuse memory device include a number of anti-fuse memory cells (or bit cells), whose terminals are disconnected before programming, and are shorted (e.g., connected) after the programming. The anti-fuse memory device may be based on metal-oxide-semiconductor (MOS) technology. For example, an anti-fuse memory cell may include a programming MOS transistor (or MOS capacitor) and at least one reading MOS transistor coupled in series. A gate dielectric of the programming MOS transistor may be broken down to cause the gate and the source or drain of the programming MOS transistor to be interconnected. Depending on whether the gate dielectric of the programming MOS transistor is broken down, different data bits can be presented by the anti-fuse memory cell through reading a resultant current flowing through the programming MOS transistor and reading MOS transistor. The anti-fuse memory devices have the advantageous features of reverse-engineering proofing, since the programming states of the anti-fuse cells cannot be determined through reverse engineering.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a block diagram of an example memory device, in accordance with some embodiments.

FIG. 2 illustrates an example circuit diagram of a portion of the memory device of FIG. 1, in accordance with some embodiments.

FIG. 3 illustrates an example layout to fabricate a pair of the memory cells of FIG. 2, in accordance with some embodiments.

FIG. 4 illustrates a cross-sectional view of one of the memory cells, made based on the layout of FIG. 3, in accordance with some embodiments.

FIG. 5 illustrates an example flow chart of a method for operating at least one of the memory cells of FIG. 2, in accordance with some embodiments.

FIG. 6 illustrates an example layout to fabricate one of the memory cells of FIG. 2, in accordance with some embodiments.

FIG. 7 illustrates an example layout to fabricate a memory array including a number of the memory cells of FIG. 2, in accordance with some embodiments.

FIG. 8 illustrates another example layout to fabricate a memory array including a number of the memory cells of FIG. 2, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In general, cells of an anti-fuse memory device are formed as an array. The array includes a number of rows and a number of columns, with one cell disposed at an intersection of one of the rows and one of the columns. Each cell can be accessed (e.g., programmed) through a respective combination of a first access line disposed along the corresponding row (e.g., a word line (WL)) and a second access line disposed along the corresponding column (e.g., a bit line (BL)).

With such an array configuration, programming transistors of a number of anti-fuse cells may share one of the WLs, while their reading transistors coupled to different BLs, respectively. Alternatively stated, in order to program one of the cells in an array, a programming voltage is applied to a corresponding WL of the to-be-programmed (selected) cell. This WL is also coupled to a number of others (unselected) cells in the array. With a leakage path present in a (e.g., programming) transistor of each cell, the programming voltage (which is typically in a relatively high voltage level) can cause undesired stress on those unselected cells. For example, the leakage path can be incurred due to a gate-induced drain leakage (GIDL) effect. In turn, an overall reliability of the anti-fuse memory device can be deteriorated. Thus, the existing anti-fuse memory devices may not be entirely satisfactory in some aspects.

The present disclosure provides various embodiments of an anti-fuse memory device including a number of anti-fuse memory cells. Each of the anti-fuse memory cells, as disclosed herein, includes an anti-fuse structure and a reading transistor. The anti-fuse structure and the reading transistor are electrically coupled to each other in series. In various embodiments, the anti-fuse structure may be implemented as a first electrode and a second electrode sandwiching an insulator. One of the first or second electrode is configured to break down at least a portion of the insulator so as to electrically couple (e.g., short) the first electrode to the second electrode. Stated another way, the anti-fuse structure may not include a transistor as being typically implemented in the existing anti-fuse memory devices. With such a non-transistor anti-fuse structure, the above-identified issues (e.g., due to the almost unavoidable leakage path in transistors) may be resolved, even arranging a number of the disclosed anti-fuse memory cells as an array. In various embodiments of the present disclosure, each of the first and second electrodes can be implemented as a via structure that can be compatibly fabricated with the existing CMOS technologies. Accordingly, no additional fabrication cost or complexity should be incurred. Further, by forming one of the electrodes over a dummy gate structure disposed on the edge of an active region (sometimes referred to as Poly Over Diffusion Edge (PODE)), two of the disclosed anti-fuse memory cells can be compactly formed in such a single active region. Accordingly, a total area of such a pair of anti-fuse memory cells can be significantly reduced. For example, an array including 8×8 of the pairs of anti-fuse memory cells can have a total area about 30% smaller than the area of an array including the same number of exiting anti-fuse memory cells.

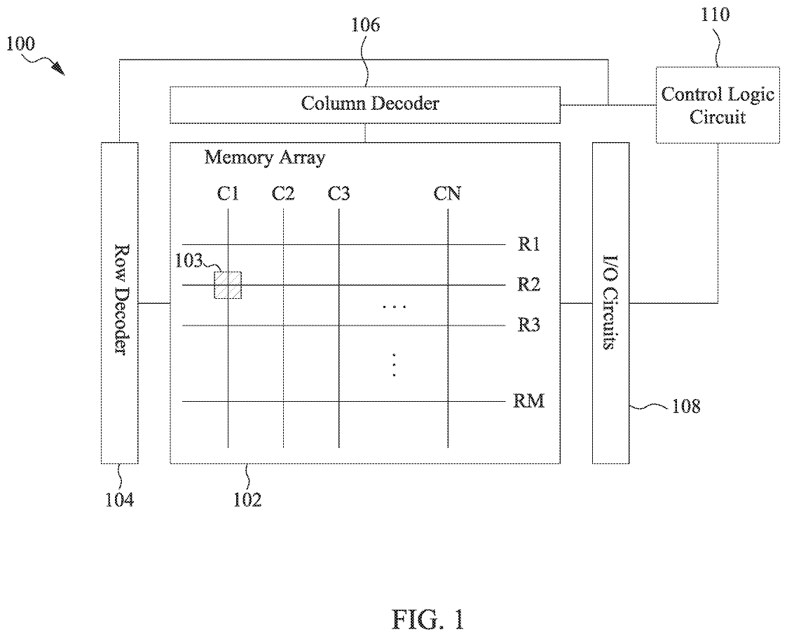

FIG. 1 illustrates a memory device 100, in accordance with various embodiments. As shown, the memory device 100 includes a memory array 102, a row decoder 104, a column decoder 106, an input/output (I/O) circuit 108, and a control logic circuit 110. Despite not being shown in FIG. 1, all of the components of the memory device 100 may be operatively coupled to each other and to the control logic circuit 112. Although, in the illustrated embodiment of FIG. 1, each component is shown as a separate block for the purpose of clear illustration, in some other embodiments, some or all of the components shown in FIG. 1 may be integrated together. For example, the memory array 102 may include an embedded I/O circuit 108.

The memory array 102 is a hardware component that stores data. In one aspect, the memory array 102 is implemented as a semiconductor memory device. The memory array 102 includes a number of memory cells (or otherwise storage units) 103. The memory array 102 includes a number of rows R₁, R₂, R₃ . . . R_{M}, each extending in a first direction (e.g., X-direction) and a number of columns C₁, C₂, C₃ . . . C_{N}, each extending in a second direction (e.g., Y-direction). Each of the rows/columns may include one or more conductive structures each configured as an access line (e.g., a programming word line (WLP), a reading word line (WLR), a bit line (BL)), which will be discussed below. In some embodiments, each memory cell 103 is arranged in the intersection of a corresponding row and a corresponding column and can be operated according to voltages or currents through the respective conductive structures of the column and row.

In various embodiments of the present disclosure, each memory cell 103 is implemented as an anti-fuse memory cell that includes an anti-fuse structure and a transistor coupled in series. The anti-fuse structure can function as a programming part of the memory cell, and the transistor can function as a reading transistor of the memory cell. The anti-fuse structure can be programmed by a WLP, and the transistor can be gated by a WLR. The anti-fuse structure can at least be formed by a number of interconnect structures of a middle-end-of-line (MEOL) networking, for example, a first via structure connecting to a gate structure and a second via structure coupling to a source/drain structure that interpose an insulator therebetween, which will be discussed below. Although the present disclosure is directed to implementing the memory cell 103 as an anti-fuse memory cell, it should be understood that the memory cell 103 can include any of various other memory cells, while remaining within the scope of present disclosure.

The row decoder 104 is a hardware component that can receive a row address of the memory array 102 and assert a conductive structure (e.g., a word line) at that row address. The column decoder 106 is a hardware component that can receive a column address of the memory array 102 and assert one or more conductive structures (e.g., a bit line, a source line) at that column address. The I/O circuit 108 is a hardware component that can access (e.g., read, program) each of the memory cells 103 asserted through the row decoder 104 and column decoder 106. The control logic circuit 110 is a hardware component that can control the coupled components (e.g., 102 through 108).

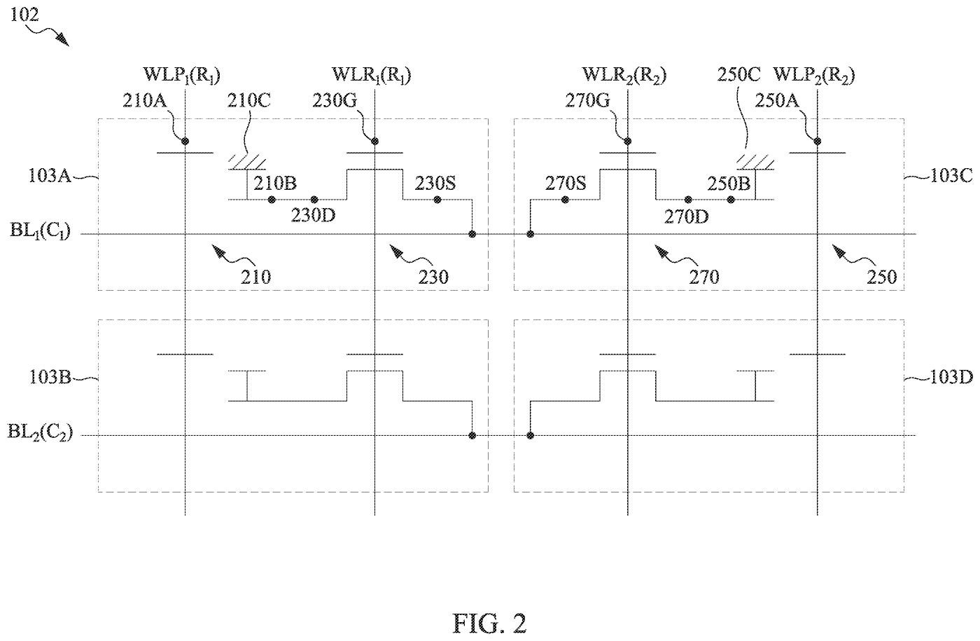

FIG. 2 illustrates an example circuit diagram of a portion of the memory device 100 (e.g., some of the memory cells 103), in accordance with some embodiments. In the illustrated example of FIG. 2, anti-fuse memory cells 130A, 130B, 130C, and 130D of the memory array 102 are shown. Although four anti-fuse memory cells 103A-D are shown, it should be appreciated that the memory array 102 can have any number of anti-fuse memory cells, while remaining within the scope of present disclosure.

As mentioned above, the memory cells 103 can be arranged as an array. In FIG. 2, the memory cells 103A and 103B may be disposed in a same row but in respectively different columns; and the memory cells 103C and 103D may be disposed in a same row but in respectively different columns. For example, the memory cells 103A and 103B are disposed in row R₁, but in columns C₁ and C₂, respectively; and the memory cells 103C and 103D are disposed in row R₂, but in columns C₁ and C₂, respectively. With such a configuration, each of the memory cells can be operatively coupled to the access lines in the corresponding row and column, respectively.

For example in FIG. 2, the memory cell 103A is operatively (e.g., electrically) coupled to a programming word line and a reading word line in row R₁ (hereinafter WLP₁ and WLR₁, respectively) and to a bit line in column C₁ (hereinafter BL₁); the memory cell 103B is operatively coupled to the WLP₁ and WLR₁ in row R₁ and to a bit line in column C₂ (hereinafter BL₂); the memory cell 103C is operatively coupled to a programming word line and a reading word line in row R₂ (hereinafter WLP₂ and WLR₂, respectively) and to the BL₁ in column C₁; and the memory cell 103D is operatively coupled to the WLP₂ and WLR₂ in row R₂ and to the BL₂ in column C₂.

In some embodiments, each of the memory cells 103A-D can be operatively coupled to the I/O circuit 108 through the respective WLR, WLP, and BL for being accessed (e.g., programmed, read). For example, the I/O circuit 108 can cause the row decoder 104 to assert the WLP₁ and WLR₁ and the column decoder 106 to assert the BL₁, so as to access the memory cell 103A through the WLP₁, WLR₁, and BL₁. Accordingly, each of the memory cells 103A-D can be individually selected to be programmed or read. Details of programming and reading the memory cell will be discussed in further detail below.

As disclosed herein, each of the memory cells 103A to 103D includes an anti-fuse structure configured for programming and a transistor configured for reading, wherein the anti-fuse structure and the transistor are coupled to each other in series. The anti-fuse structure may be embodied as a non-transistor structure, for example, a structure having a first electrode and a second electrode interposing an insulator therebetween. Specifically, one of the electrodes of the anti-fuse structure (implemented as a first via structure) is coupled to a WLP, and the other of the electrodes of the anti-fuse structure (implemented as a second via structure) is electrically coupled to one of the source/drain structures of the transistors; and the transistor is gated by a WLR, with the other of the source/drain structures electrically coupled to a BL, in accordance with various embodiments. The memory cell 103A is selected as a representative example in the following discussions.

Referring still to FIG. 2, the memory cell 103A includes a (programming) anti-fuse structure 210, and a (reading) transistor 230. The programming anti-fuse structure 210 is coupled to the reading transistor 230 in series. The anti-fuse structure 210 has a first electrode 210A and a second electrode 210B that interpose an insulator 210C; and the transistor 230 has a first terminal (implemented as a drain structure) 230D, a second terminal (implemented as a gate structure) 230G, and a third terminal (implemented as a source structure) 230S. In various embodiments, the anti-fuse structure 210 has the first electrode 210A, which is formed as a first via structure connected to a gate structure (sometimes referred to as “VG”), connected to WLP₁. Further, the anti-fuse structure 210 has the second electrode 210B, which is formed as a second via structure (sometimes referred to as “VD”) connected to a source/drain interconnect structure (sometimes referred to as “MD”), electrically coupled to the drain structure 230D, thereby serially connecting the anti-fuse structure 210 to the transistor 230. The transistor 230 is gated by WLR₁, with the source structure 230S electrically coupled to BL₁.

Similarly, the memory cell 103C includes a (programming) anti-fuse structure 250, and a (reading) transistor 270. The programming anti-fuse structure 250 is coupled to the reading transistor 270 in series. The anti-fuse structure 250 has a first electrode 250A and a second electrode 250B that interpose an insulator 250C; and the transistor 270 has a first terminal (implemented as a drain structure) 270D, a second terminal (implemented as a gate structure) 270G, and a third terminal (implemented as a source structure) 270S. In various embodiments, the anti-fuse structure 250 has the first electrode 250A, which is formed as a third via structure connected to a gate structure (e.g., a VG), connected to WLP₂. Further, the anti-fuse structure 250 has the second electrode 250B, which is formed as a fourth via structure (e.g., a VD) connected to a source/drain interconnect structure (sometimes referred to as an MD), electrically coupled to the drain structure 270D, thereby serially connecting the anti-fuse structure 250 to the transistor 270. The transistor 270 is gated by WLR₂, with the source structure 270S electrically coupled to BL₁.

In accordance with various embodiments of the present disclosure, at least some of the features/structures of the anti-fuse structure 210 (e.g., VG, VD) and interconnect structure(s) connecting the anti-fuse structure 210 to the transistor 230 (e.g., MD) are a portion of a middle-end-of-line (MEOL) networking, which generally refers to a collection of interconnect structures of a “middle networking” between a front-end-of-line (FEOL) networking and a back-end-of-line (BEOL) networking. The terms FEOL networking and BEOL networking typically refer to a collection of active/dummy features formed along the major surface of a substrate (e.g., a transistor and its features/structures) and a collection of interconnect structures (e.g., MO) formed in one or more metallization layers over the substrate, respectively. Details of these FEOL/MEOL/BEOL structures that construct at least a portion of the memory array 102 will be discussed below.

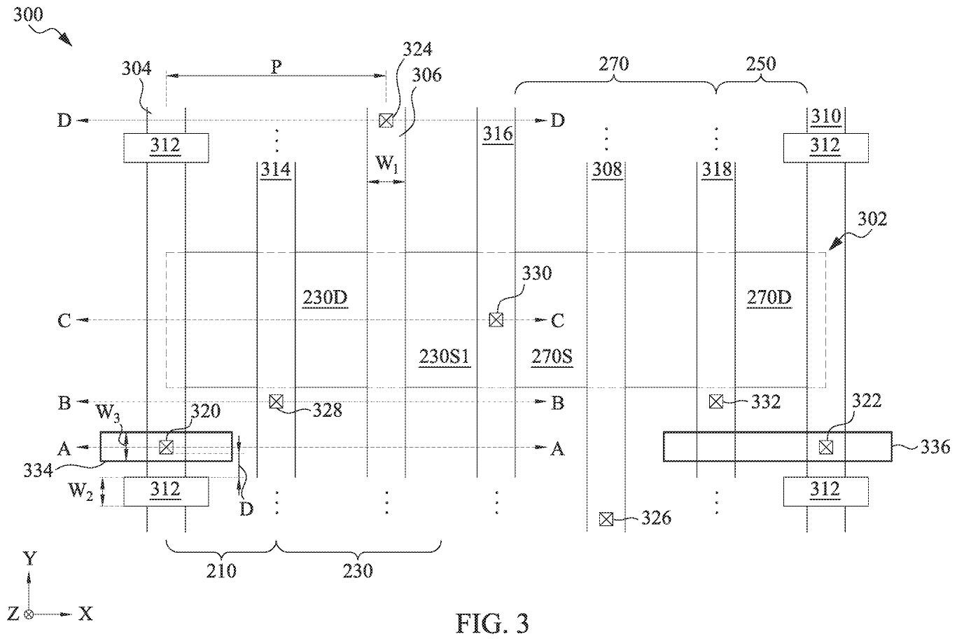

FIG. 3 illustrates an example layout 300 of a portion of the memory array 102, which includes two of the disclosed anti-fuse memory cells coupled to a same BL (e.g., 103A and 103C of FIG. 2), in accordance with various embodiments. As will be discussed below, these two memory cells may share (e.g., be formed over) a common active region, which can advantageously reduce an area of the memory array 102 as a whole.

As shown, the layout 300 includes: pattern 302 that is configured to form an active region (hereinafter “active region 302”); patterns 304, 306, 308, and 310 that are each configured to form a gate structure (hereinafter “gate structure 304,” “gate structure 306,” “gate structure 308,” and “gate structure 310,” respectively); a number of patterns 312 that are each configured to form a dielectric structure separating or otherwise cutting a corresponding gate structure (hereinafter “cut structure 312”); pattern 314, 316, and 318 that are each configured to form a source/drain interconnect structure, e.g., MD, (hereinafter “MD 314,” “MD 316,” and “MD 318,” respectively); patterns 320, 322, 324, and 326 that are each configured to form a gate via structure, e.g., VG (hereinafter “VG 320,” “VG 322,” “VG 324,” and “VG 326,” respectively); patterns 328, 330, and 332 that are each configured to form a source/drain via structure, e.g., VD (hereinafter “VD 328,” “VD 330,” and “VD 332,” respectively); and patterns 334 and 336 that are each configured to form an interconnect structure in a bottommost metallization layer, e.g., MO (hereinafter “MO 334” and “MO 336,” respectively).

The active region 302 may extend along a first lateral direction (e.g., X-direction), while the gate structures 304 to 310 and MDs 314 to 318 may extend along a second, different lateral direction (e.g., Y-direction). Further, the gate structures 304 and 310 may extend along opposite edges of the active region 302, while the gate structures 306 and 308 may each travel across a non-edge portion of the active region 302. Interposed between adjacent ones of the gate structures, one of the MDs can travel across the active region 302. For example in FIG. 3, the MD 314 travels across a portion of the active region 302 between the gate structures 304 and 306; the MD 316 travels across a portion of the active region 302 between the gate structures 306 and 308; and the MD 318 travels across a portion of the active region 302 between the gate structures 308 and 310. In some embodiments, each of the cut structures 312 can (e.g., along the Y-direction) travel across a corresponding gate structure to cut it into a number of separated portions. For example in FIG. 3, two cut structures 312 travel across the gate structure 304 to cut it into three separated portions; and two other cut structures 312 travel across the gate structure 310 to cut it into three separated portions. In some embodiments, the cut structures 312 can be formed to isolate a number of memory cells (e.g., 2 memory cells in FIG. 3) from other memory cells of the memory array 102.

The active region 302 can be formed as a (e.g., planar) region recessed in a major surface of a substrate or a (e.g., non-planar) stack structure protruding from the major surface of the substrate. The planar region and the non-planar stack can be used to form a number of planar transistors and a number of non-planar transistors, respectively. The following discussions will be focused on non-planar transistors (e.g., Fin Field-Effect-Transistors (FinFETs), Gate-All-Around (GAA) FETs).

For example, to form the (reading) transistors of the disclosed anti-fuse memory cells as GAA FETs, the stack can include a number of semiconductor nanostructures (e.g., nanosheets) extending along the X-direction and vertically separated from each other. Portions of the semiconductor structures in the stack that are overlaid by the gate structures 304 through 310 remain, while other portions are replaced with a number of epitaxial structures.

The remaining portions of the semiconductor structures (i.e., the portions of the active region 302 that are overlaid by the gate structures) can be configured as the channel of a corresponding transistor. The epitaxial structures coupled to both sides (or ends) of the remaining portions of the semiconductor structures can be configured as source/drain structures (or terminals) of the transistor. A portion of the gate structure that overlays (e.g., straddles) the remaining portions of the semiconductor structures can be configured as a gate structures (or terminal) of the transistor.

According to some embodiments of the present disclosure, the gate structures 306 and 308, that are not disposed in edge portions of the active region 302, can serve as respective active gate structures of corresponding transistors; and the gate structures 304 and 310, that are disposed along edges of the active region 302, can serve as dummy gate structures. An active gate structure generally refers to the gate that is configured to turn on and off a corresponding transistor, and a dummy gate structure generally refers to the gate that is not configured to turn on or off a corresponding transistor.

For example, a first portion of the active region portion 302 that is overlaid by the gate structure 306 may include a number of nanostructures vertically separated from each other, which can function as a channel of the reading transistor 230 (FIG. 2). The gate structure 306 may function as the gate structure 230G of the reading transistor 230. Portions of the active region portion 302 that are disposed on opposite sides of the gate structure portion 306 are replaced with epitaxial structures, which can function as the source/drain structures 230D and 230S of the reading transistor 230 (FIG. 2), respectively. Similarly, a second portion of the active region portion 302 that is overlaid by the gate structure 308 may include a number of nanostructures vertically separated from each other, which can function as a channel of the reading transistor 270 (FIG. 2). The gate structure 308 may function as the gate structure 270G of the reading transistor 270. Portions of the active region portion 302 that are disposed on opposite sides of the gate structure portion 308 are replaced with epitaxial structures, which can function as the source/drain structures 270D and 270S of the reading transistor 270, respectively. It should be noted that the reading transistors 230 and 270 may share a same portion of the active region 302 to form their respective source structures 230S and 270S, as shown in FIG. 3.

Each of the MDs 314 to 318 is formed to connect to a corresponding one of the source/drain structures. For example, the MD 314 connects to the drain structure 230D of the reading transistor 230; the MD 316 connects to the source structure 230S of the reading transistor 230 and the source structure 270S of the reading transistor 270; and the MD 318 connects to the drain structure 270D of the reading transistor 270. Further, each of the VGs 320 to 326 is formed to connect to a corresponding one of the gate structures 304 to 310; and each of the VDs 328 to 332 is formed to connect to a corresponding one of the MDs 314 to 318. For example, the VG 320 connects to the gate structure 304; the VG 322 connects to the gate structure 310; the VG 324 connects to the gate structure 306; the VG 326 connects to the gate structure 308; the VD 328 connects to the MD 314; the VD 330 connects to the MD 316; and the VD 332 connects to the MD 318.

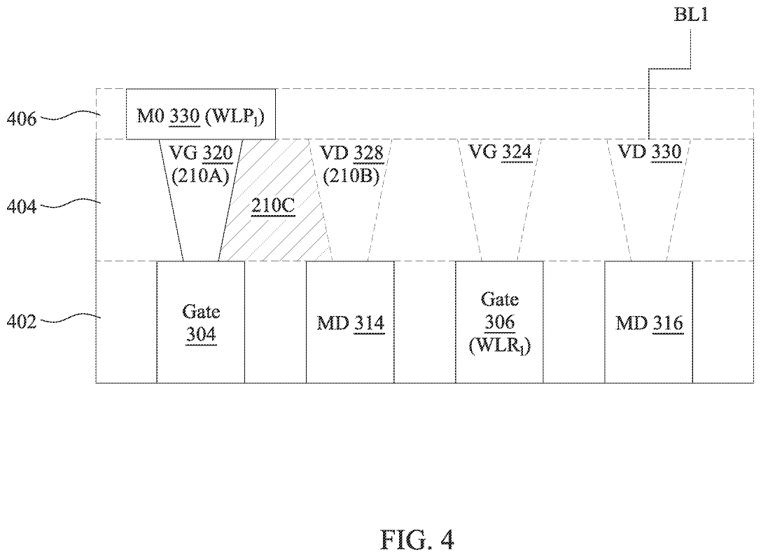

According to various embodiments of the present disclosure, the VG 320 and VD 328 can function as the first electrode 210A and second electrode 210B of the anti-fuse structure 210 (FIG. 2), respectively; and the VG 322 and VD 332 can function as the first electrode 250A and second electrode 250B of the anti-fuse structure 250 (FIG. 2), respectively. The VGs and VDs are typically formed in a same metallization layer, as will be illustrated in the cross-sectional view of FIG. 4. In general, such a metallization layer includes a dielectric material (sometimes referred to as an interlayer/intermetal dielectric) the embeds a number of interconnect structures. The dielectric material is formed of a low-k dielectric material such as silicon oxide, silicon nitride, silicon carbide, silicon carbonitride, silicon oxynitride, silicon oxycarbonitride, or the like. A portion of such a dielectric material interposed between the corresponding VG and VD of an anti-fuse structure can function as an insulator of the anti-fuse structure. For example, a first portion of a dielectric material (embedding the VGs 320 to 326 and VDs 328 to 332) that is interposed between the VG 320 and VD 328 can function as the insulator of the anti-fuse structure 210; and a second portion of the same dielectric material (embedding the VGs 320 to 326 and VDs 328 to 332) that is interposed between the VG 322 and VD 332 can function as the insulator of the anti-fuse structure 250.

Each of the VGs 320 to 326 and VDs 328 to 332 is formed to (e.g., electrically) couple an underlying structure to one or more interconnect structures disposed in an upper metallization layer, thereby operatively coupling different anti-fuse memory cells to each other as an array. For example, the VG 320 can couple the gate structure 304 (despite functioning as a dummy gate) to the MO 330; and the VD 330 can couple the MD 316 (and the underlying source structures 230S and 270S) to an interconnect structure disposed in an upper metallization layer that functions as BL₁, which can be better illustrated in the cross-sectional view of FIG. 4.

FIG. 4 illustrates a hybrid cross-sectional view of a portion of the memory array 102 (e.g., the memory cell 103A having the anti-fuse structure 210 and the transistor 230) formed based on the example layout 300 of FIG. 3. Specifically, FIG. 4 includes four cross-sections of the portion of the memory array 102, which are cut along line A-A, line B-B. line C-C, and line D-D (as indicated in FIG. 3), respectively. In FIG. 4, the structures(s) present in at least the cross-section A-A are shown in solid lines, and the structure(s) present in only one of the cross-section B-B, C-C, or D-D are shown in dotted lines.

As shown, the gate structures 304 and 306 and the MDs 314 and 316 are embedded in a first dielectric material 402, the VGs 320 and 324 and the VDs 328 and 330 are embedded in a second dielectric material 404, and the MO 330 is embedded in a third dielectric material 406. Each of the first to third dielectric materials 402 to 406 includes the above-described low-k dielectric material. As at least partially described above, the VG 320 and VD 328 can function as the first electrode 210A and second electrode 210B of the anti-fuse structure 210 of the memory cell 103A (FIG. 2), respectively. The VG 320 and VD 328 interpose a portion of the dielectric material 404 (filled with diagonal lines) therebetween. Such a portion of the dielectric material 404 can function as the insulator 210C of the anti-fuse structure 210. The MO 330, connected to the VG 320, can function as WLP₁ configured to program the anti-fuse structure 210. The VD 328 is connected to the MD 314, which is connected to the drain structure 230D of the transistor 230 of the memory cell 103A, thereby causing the anti-fuse structure 210 and transistor 230 to be connected to each other in series. The transistor 230 is gated by the gate structure 306, which can function as WLR₁ that allows access of the memory cell 103A. Further, the transistor 230 has the source structure 230S connected to the MD 316. The VD 330 can couple the MD 316 (and the source structure 230S) to BL₁, which may be formed in an upper metallization layer (e.g., a fourth dielectric material).

It should be appreciated that the dimensions of each of the above-described structures and how these structures are arranged with each other can be optimized according to a certain technology node. Referring again to the layout 300 of FIG. 3, several dimensions of the structures and how these structures are arranged with each other are provided in the following discussions as a non-limiting example. At a certain technology node, the gate structures 304 to 310 can each have a width along the X-direction (W₁) of about 20 nanometers (nm) to about 40 nm, and the neighboring gate structures can have a spacing or pitch also along the X-direction (P) of about 99 nm to about 120 nm. The cut structure 312 can have a width along the Y-direction (W₂) of about 15 nm to about 25 nm, and a spacing along the Y-direction between the VG 320 and the cut structure 312 (D) is about 5 nm to about 10 nm. The MOs 334 and 336 can each have a width along the Y-direction (W₃) of about 10 nm to about 30 nm, and the neighboring MOs can have a spacing or pitch also along the Y-direction of about 5 nm to about 15 nm.

Further, the VG 320 (and even the VD 328) can have a width along the Y-direction wider than the width (W₃) of the MO by about 1 nm to about 5 nm, although the example FIG. 3 shows the contrary. Still further, a spacing along the X-direction between the VG 320 and VD 328 can be adjusted with a margin of about 1 nm to about 5 nm. As such, a breakdown voltage (which will be discussed below) of the anti-fuse structure 210 may change accordingly. For example, a narrower spacing between the VG 320 and VD 320 may correspond to a lower breakdown voltage, while a wider spacing between the VG 320 and VD 320 may correspond to a higher breakdown voltage.

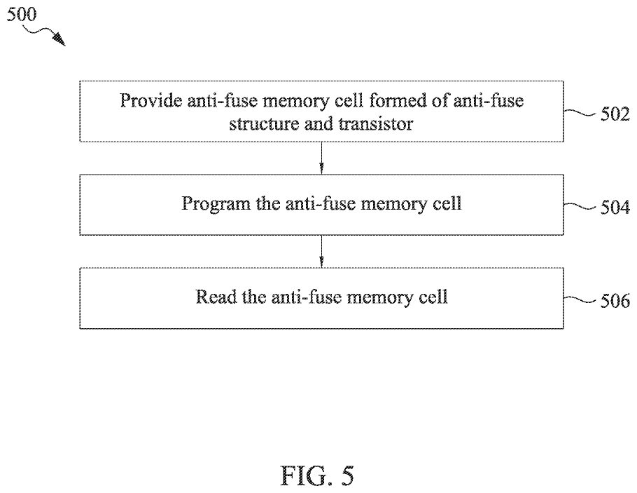

FIG. 5 illustrates a flow chart of an example method 500 for operating (e.g., programming and/or reading) the disclosed anti-fuse memory cell (e.g., 103A, 103B, 103C, 103D), in accordance with various embodiments. The operations of the method 500 can be performed through one or more features/structures illustrated above. Accordingly, the following embodiment of the method 500 will be described in conjunction with at least some of the figures above. The illustrated embodiment of the method 500 is merely an example. Therefore, it should be understood that any of a variety of operations may be omitted, re-sequenced, and/or added while remaining within the scope of the present disclosure.

The method 500 starts with operation 502 of providing an anti-fuse memory cell formed of an anti-fuse structure and a reading transistor, in accordance with various embodiments. For example, as disclosed herein, the anti-fuse structure (e.g., 210) of the anti-fuse memory cell (e.g., 103A) includes a first electrode (e.g., 210A) implemented as a first via structure (e.g., 320) and a second electrode (e.g., 210B) implemented as a second via structure (e.g., 328) that interpose an insulator (e.g., a portion of the dielectric material 404 embedding the first and second via structures, 320 and 328) therebetween, and the anti-fuse structure is electrically coupled to the reading transistor (e.g., 230) in series through the second via structure and an underlying interconnect structure (e.g., 314). Further, the first electrode of the anti-fuse structure is coupled to a programming word line (e.g., WLP₁), and a gate structure (e.g., 306) of the reading transistor may function as or be coupled to a reading word line (e.g., WLR₁) with a source structure (e.g., 230S) of the reading transistor coupled to a bit line (e.g., BL₁).

Next, the method 500 proceeds to operation 504 of programming the memory cell 103A, in accordance with various embodiments. To program the memory cell 103A, the reading transistor 230 is turned on by supplying a high enough voltage (e.g., a positive voltage corresponding to a logic high state) to its gate structure 306. Prior to, concurrently with or subsequently to the reading transistor 230 being turned on, a sufficiently high voltage (e.g., a breakdown voltage (V_{BD}) which is sometimes referred to as a programming voltage) is applied to WLP₁, and a low enough voltage (e.g., a positive voltage or ground voltage corresponding to a logic low state) is applied to BL₁. With the reading transistor 230 being turned on, the low voltage (applied on BL₁) can be passed to the drain structure 230D (and also the electrically coupled second electrode 210B, e.g., the via structure 328). As such, the programming voltage V_{BD} can be present across the first electrode 210A (e.g., the via structure 320) and the second electrode 210B thereby causing a breakdown of the interposed insulator 210C.

When operating an array of composed of a number of the disclosed memory cells, leakage current typically present between the gate structure and source/drain structure of an unselected programming transistor can be almost eliminated. The commonly high voltage level of the programming voltage can cause the leakage current to become worse. In the present disclosure, the typical programming transistor is replaced by a non-transistor structure (e.g., the disclosed anti-fuse structure), which in turn minimizes such leakage current.

After the insulator 210C of the anti-fuse structure 210 is broken down, a behavior of the insulator 210C is equivalently resistive. For example, such a broken-down portion of the dielectric material 404 (that is configured as the insulator 210C) may function as a resistor. Before the insulator 210C is broken down, no conduction path exists between the first and second electrodes, 210A and 210B, even if the reading transistor 230 is turned on. After programming the anti-fuse structure 210 (e.g., by breaking down the insulator 210C), a conduction path exists between the first and second electrodes, 210A and 210B (e.g., via the equivalently formed resistor).

Next, the method 500 continues to operation 506 of reading the memory cell 103A, in accordance with various embodiments. To read the memory cell 103A, similarly to the programming, the reading transistor 230 is turned on via WLR₁, and BL₁ is coupled to a voltage corresponding to the logic low state. In response, a positive voltage is applied to the first electrode 210A of the anti-fuse structure 210 through WLP₁. As discussed above, if the insulator 210C of the anti-fuse structure 210 is not broken down, no conduction path exists between the first and second electrodes of the anti-fuse structure 210. Thus, a relatively low current conducts from WLP₁, through the anti-fuse structure 210 and the reading transistor 230, and to BL₁. If the insulator 210C of the anti-fuse structure 210 is broken down, a conduction path exists between the first and second electrodes of the anti-fuse structure 210. Thus, a relatively high current conducts from WLP₁, through the anti-fuse structure 210 and the reading transistor 230, and to BL₁.

Such a low current and high current may sometimes be referred to as I_{off} and Iₒₙ of the memory cell 103A, respectively. A circuit component (e.g., a sense amplifier) of the I/O circuit 108 (FIG. 1), coupled to the BL₁ can differentiate I_{off} from Iₒₙ (or vice versa), and thus determine whether the memory cell 103A presents a logic high (“1”) or a logic low (“0”) based on whether a conduction path is formed in the anti-fuse structure 210. Accordingly, the anti-fuse structure can sometimes be referred to as a memory structure of the anti-fuse memory cell 103A. For example, when Iₒₙ is read, the memory cell 103A may present 1; and when I_{off} is read, the memory cell 103A may present 0.

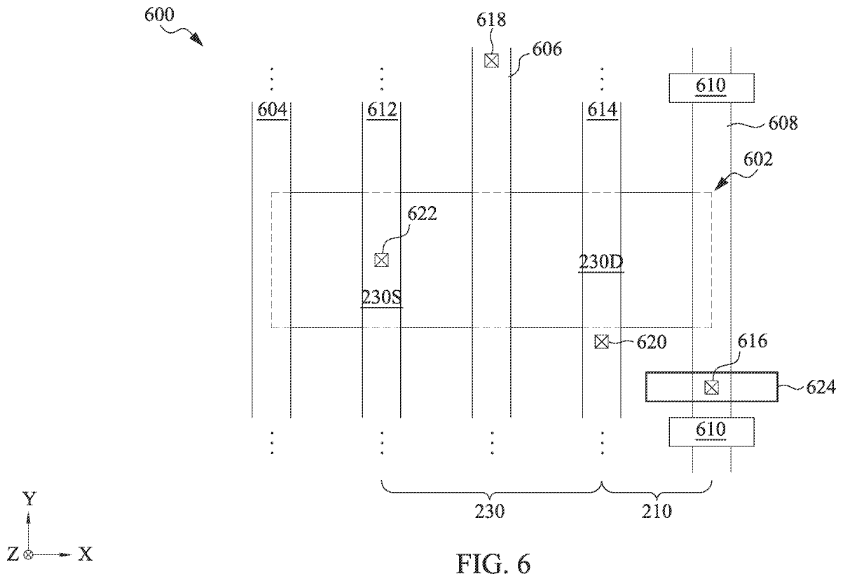

FIG. 6 illustrates another example layout 600 of a portion of the memory array 102, which includes one of the disclosed anti-fuse memory cells (e.g., 103A, 103B, 103C, or 103D of FIG. 2), in accordance with various embodiments. Different from the layout 300 shown in FIG. 3, the memory cell may exclusively occupy (e.g., be formed over) a single active region.

As shown, the layout 600 includes: pattern 602 that is configured to form an active region (hereinafter “active region 602”); patterns 604, 606, and 608 that are each configured to form a gate structure (hereinafter “gate structure 604,” “gate structure 606,” and “gate structure 608,” respectively); a number of patterns 610 that are each configured to form a dielectric structure separating or otherwise cutting a corresponding gate structure (hereinafter “cut structure 610”); pattern 612 and 614 that are each configured to form a source/drain interconnect structure, e.g., MD, (hereinafter “MD 612” and “MD 614,” respectively); patterns 616 and 618 that each configured to form a gate via structure, e.g., VG (hereinafter “VG 616” and “VG 618,” respectively); patterns 620 and 622 that each configured to form a source/drain via structure, e.g., VD (hereinafter “VD 620” and “VD 622,” respectively); and pattern 624 that is configured to form an interconnect structure in a bottommost metallization layer, e.g., MO (hereinafter “MO 624”).

The structures (or patterns) shown in the layout 600 are substantially similar to those shown in the layout 300 of FIG. 3, and thus, those structures of the layout 600 will be briefly described as follows. The gate structure 608, disposed along an edge of the active region 602, is configured as a dummy gate, while the gate structure 606 is configured as an active gate structure. The cut structures 610 can isolate the memory cell formed in the active region 602 from other memory cells of the array 102. The VG 616 and VD 620 can function as the first electrode 210A and second electrode 210B of the anti-fuse structure 210 (FIG. 2), respectively, and a portion of the dielectric material interposed between the VG 616 and VD 620 can function as the insulator 210C of the anti-fuse structure 210 The (active) gate structure 606 can function as the gate structure 230G of the reading transistor 230 (FIG. 2), and portions of the active region 602 disposed on opposite sides of the gate structure 606 function as the drain stricture 230D and source structure 230S of the reading transistor 230, respectively. The MD 614 is connected to the drain structure 230D, which is coupled to the VD 620, thereby causing the anti-fuse structure 210 and reading transistor 230 to couple to each other in series. Further, the MO 624 can function as WLP₁; the gate structure 606 can function as (or be coupled to) WLR₁; and the source structure 230S can be coupled to BL₁ (formed as an interconnect structure in an upper metallization layer) through the MD 612 and then the VD 622.

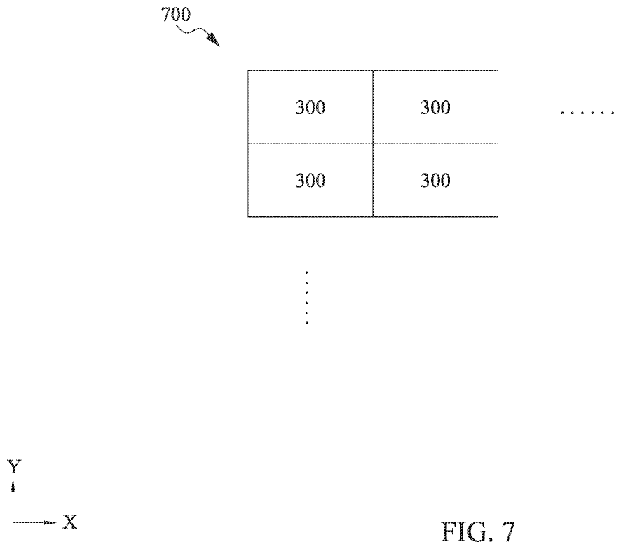

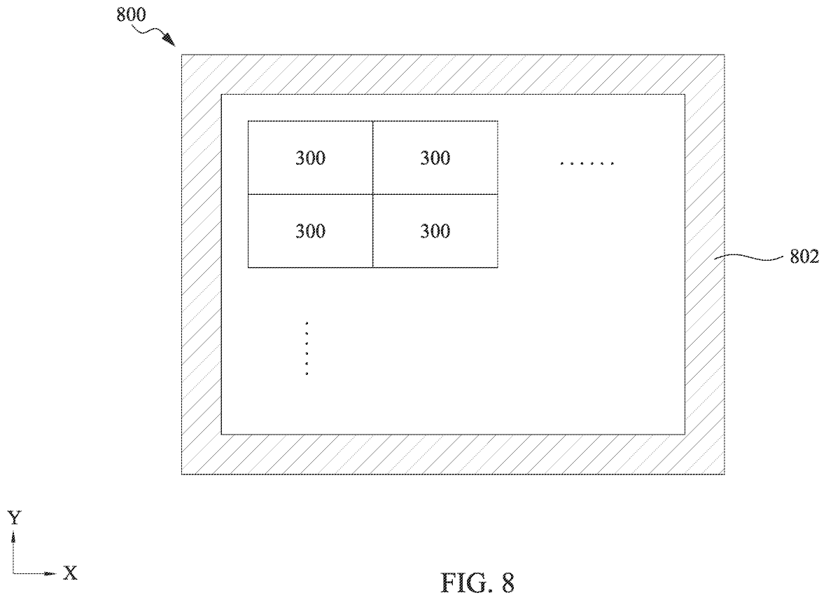

According to various embodiments, the layout 300 (FIG. 3) or 600 (FIG. 6) can be used to fabricate an anti-fuse memory array (e.g., 102) having a number of the disclosed anti-fuse memory cells. For example, a layout used to fabricate an anti-fuse memory array may include a number of the layouts similar as 300 or 600 that are repeatedly arranged along the X-direction and Y-direction. For example, FIG. 7 illustrates an example layout 700 having the layouts 300 repeatedly arranged in both of the X-direction and Y-direction. In another example, FIG. 8 illustrates another example layout 800 having the layouts 300 repeatedly arranged in both of the X-direction and Y-direction, and surrounded by a guard ring 802. The guard ring 802 can (e.g., electrically) isolate the memory array enclosed therein. In some embodiments, the guard ring includes a number of structures (e.g., dummy transistors) formed in an active region having a conductive type opposite to a conductive type of the active region in which the structures of the memory array are formed. For example, when the transistors of the anti-fuse memory cells are formed in a p-type active region, the guard ring 802 is formed in an n-type active region, and vice versa.

In one aspect of the present disclosure, a memory device is disclosed. The memory device includes a first memory cell including a first transistor and a first anti-fuse structure electrically coupled to each other in series. The first transistor includes a first gate structure extending across an active region, a first source/drain structure disposed in a first portion of the active region, and a second source/drain structure disposed in a second portion of the active region. The first anti-fuse structure includes a first electrode electrically coupled to the first source/drain structure, a second electrode disposed over a first dummy gate structure, and a first insulator laterally interposed between the first electrode and the second electrode.

In another aspect of the present disclosure, a memory device is disclosed. The memory device includes a first memory cell including a first transistor and a first memory structure electrically coupled to each other in series. The memory device includes a second memory cell including a second transistor and a second memory structure electrically coupled to each other in series, the first transistor and second transistor sharing a same active region. The first memory structure includes a first insulator laterally interposed between a first via structure and a second via structure, and the second memory structure includes a second insulator laterally interposed between a third via structure and a fourth via structure.

In yet another aspect of the present disclosure, a method for operating a memory device is disclosed. The method includes activating a transistor of a memory cell by applying a first voltage to a first gate structure of the transistor. The method includes breaking down an insulator laterally interposed between a first via structure and a second via structure by applying a second voltage on the second via structure, thereby programming the memory cell. The second via structure is vertically disposed over a second gate structure, and the first via structure is vertically disposed over an interconnect structure that is laterally interposed between the first gate structure and the second gate structure.

As used herein, the terms “about” and “approximately” generally mean plus or minus 10% of the stated value. For example, about 0.5 would include 0.45 and 0.55, about 10 would include 9 to 11, about 1000 would include 900 to 1100.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory device, comprising:
a first memory cell including a first transistor and a first anti-fuse structure electrically coupled to each other in series;
wherein the first transistor includes a first gate structure extending across an active region, a first source/drain structure disposed in a first portion of the active region, and a second source/drain structure disposed in a second portion of the active region; and
wherein the first anti-fuse structure includes a first electrode electrically coupled to the first source/drain structure, a second electrode disposed over a first dummy gate structure, and a first insulator laterally interposed between the first electrode and the second electrode.

2. The memory device of claim 1, wherein the first dummy gate structure extends along a first edge of the active region.

3. The memory device of claim 1, further comprising a first interconnect structure vertically interposed between the first source/drain structure and the first electrode.

4. The semiconductor device of claim 1, wherein a programming voltage applied to the second electrode is configured to break down the first insulator.

5. The memory device of claim 1, further comprising:
a second memory cell including a second transistor and a second anti-fuse structure electrically coupled to each other in series;
wherein the second transistor includes a second gate structure extending across the active region, a third source/drain structure disposed in a third portion of the active region, and a fourth source/drain structure disposed in a fourth portion of the active region; and
wherein the second anti-fuse structure includes a third electrode disposed electrically coupled to the third source/drain structure, a fourth electrode disposed over a second dummy gate structure, and a second insulator laterally interposed between the third electrode and the fourth electrode.

6. The memory device of claim 5, wherein the first dummy gate structure and second dummy gate structure extend along a first edge and a second edge of the active region, respectively.

7. The memory device of claim 5, wherein the second portion of the active region and the second portion of the active region merge together.

8. The memory device of claim 5, further comprising a second interconnect structure vertically interposed between the third source/drain structure and the third electrode.

9. The memory device of claim 5, wherein the first through fourth electrodes are each formed as a via structure.

10. The memory device of claim 5, wherein the active region extend along a first lateral direction, while the first and second dummy gate structures, and the first and second gate structures each extend along a second lateral direction perpendicular to the first lateral direction.

11. A memory device, comprising:
a first memory cell including a first transistor and a first memory structure electrically coupled to each other in series; and
a second memory cell including a second transistor and a second memory structure electrically coupled to each other in series, the first transistor and second transistor sharing a same active region;
wherein the first memory structure includes a first insulator laterally interposed between a first via structure and a second via structure, and the second memory structure includes a second insulator laterally interposed between a third via structure and a fourth via structure.

12. The memory device of claim 11, wherein the second via structure is configured to apply a first breakdown voltage on the first insulator to short the second and first via structures, and the fourth via structure is configured to apply a second breakdown voltage on the second insulator to short the fourth and third via structures.

13. The memory device of claim 11, wherein the second via structure and fourth via structure are in direct contact with a first dummy gate structure and a second dummy gate structure, respectively.

14. The memory device of claim 13, wherein the first dummy gate structure and second dummy gate structure extend along opposite edges of the active region, respectively.

15. The memory device of claim 14, wherein the first transistor includes a first gate structure and the second transistor includes a second gate structure, and wherein the first and second dummy gate structures, and the first and second gate structures are in parallel with each other.

16. The memory device of claim 15, wherein the active region include a portion laterally interposed between the first and second gate structures, wherein the first transistor includes a second source/drain structure and the second transistor includes a fourth source/drain structure, and wherein the second and fourth source/drain structures are disposed in the portion of the active region.

17. The memory device of claim 15, wherein the first and third via structures are in direct contact with a first interconnect structure and a second interconnect structure, respectively, the first interconnect structure laterally interposed between the first dummy gate structure and the first gate structure, the second interconnect structure laterally interposed between the second dummy gate structure and the second gate structure.

18. The memory device of claim 17, wherein the first transistor includes a first source/drain structure and the second transistor includes a third source/drain structure, and wherein the first source/drain structure and third source/drain structure are in direct contact with the first interconnect structure and the second interconnect structure, respectively.

19. A method for operating a memory device, comprising:
activating a transistor of a memory cell by applying a first voltage to a first gate structure of the transistor; and
breaking down an insulator laterally interposed between a first via structure and a second via structure by applying a second voltage on the second via structure, thereby programming the memory cell;
wherein the second via structure is vertically disposed over a second gate structure, and the first via structure is vertically disposed over an interconnect structure that is laterally interposed between the first gate structure and the second gate structure.

20. The method of claim 19, wherein the second gate structure extends along an edge of an active region, while the first gate structure extends across the active region with two portions of the active region disposed on opposite sides of the first gate structure.
